(19) United States
(12) Patent Application Publication
(10) Pub. No.: US 2016/0149070 A1
(43) Pub. Date: May 26, 2016

(54) LIGHT-RECEIVING ELEMENT AND PRODUCTION METHOD THEREFOR

(71) Applicant: V TECHNOLOGY CO., LTD., Kanagawa (JP)

(72) Inventors: Koichi Kajiyama, Kanagawa (JP); Yoshinori Ogawa, Kanagawa (JP)

(73) Assignee: V TECHNOLOGY CO., LTD., Kanagawa (JP)

(21) Appl. No.: 14/899,179

(22) PCT Filed: Apr. 23, 2014
(86) PCT No.: PCT/JP2014/061383

§ 371 Date: Dec. 17, 2015

(30) Foreign Application Priority Data
Jun. 26, 2013 (JP) 2013-134373

(51) Int. Cl. H01L 31/103; H01L 31/0224; H01L 31/18

(52) U.S. Cl. CPC H01L 31/103; H01L 31/18; H01L 31/0224

(57) ABSTRACT

A light-receiving element includes a semiconductor layer with a pn junction part and a pair of electrodes that interpose the pn junction part. Near field light is generated in the vicinity of the pn junction part by applying a forward bias voltage between the pair of electrodes and irradiating the pn junction with light that has a specific wavelength, and an electrode of the irradiated pair of electrodes is configured with a wire grid polarizer that transmits the light that has the specific wavelength.

### TECHNICAL FIELD

One or more embodiments of the present invention relate to a light-receiving element and a production method therefor.

### BACKGROUND ART

In the related art disclosed in Patent Literature 1 listed below, in order to easily produce a light-receiving element that is sensitive to light having a specific wavelength without performing selection of a material, near field light (dressed photon) is generated in a semiconductor layer by applying a special anneal process on the semiconductor layer having a pn junction part formed between electrodes, and thus, a generation site of the near field light is set as a light-receiving portion that is sensitive to light having a desired wavelength.

Herein, the anneal process is a process of applying a forward bias voltage to the semiconductor layer having the pn junction part and irradiating the semiconductor layer with light, so that the light-receiving portion that is sensitive to a wavelength of the irradiated light is obtained.

### CITATION LIST

### Patent Literature

Patent Literature 1: JP 2012-169565 A

### SUMMARY OF INVENTION

In general, in order to obtain a light-receiving element that is sensitive to long wavelength light such as near infrared wavelength light or infrared ray, band gap energy of a light-receiving portion needs to be lower than light energy of the received long-wavelength light, and the light energy is inversely proportional to the wavelength. Therefore, a material of the light-receiving portion needs to be restricted. In general, a semiconductor material having a small band gap such as Hg_{1-X}Cd_{X}Te or InSb, a multiple-quantum well layer or the like is used for the light-receiving portion for the long-wavelength light. However, these have disadvantages such as adverse effect on a human body, instability of a material, difficulty in a device process, and complexity of a production process.

In contrast, like the above-described related art, a light-receiving element obtained by a new light excitation system using near field light solves the above-described disadvantages associated with material selection restricted according to the band gap, and thus, a light-receiving portion that is sensitive to an arbitrary wavelength can be obtained by using the light having a specific wavelength that is irradiated in the anneal process. However, according to the related art, since the anneal process of applying a forward bias voltage and irradiating with the light is performed, one of electrodes interposing a pn junction part needs to be set as a light-transmission electrode. Since a transparent electrode such as ITO cannot transmit mid-infrared ray having a wavelength of 2.5 μm or more, a light-receiving element that is sensitive to long-wavelength light such as mid-infrared ray cannot be obtained.

One or more embodiments of the present invention solve various disadvantages associated with material selection restricted according to a band gap. Furthermore, one or more embodiments of the present invention is able to easily obtain a light-receiving element, such as mid-infrared ray, that is sensitive to long-wavelength light.

One or more embodiments of the present invention have at least the configuration as follows.

The light-receiving element includes a semiconductor layer including a pn junction part and a pair of electrodes interposing the pn junction part, in which near field light is generated in the vicinity of the pn junction part by applying a forward bias voltage between the pair of electrodes and irradiating with light having a specific wavelength, and an electrode of the pair of electrodes that is irradiated with the light is configured with a wire grid polarizer that transmits the light having the specific wavelength.

### Advantageous Effects of Invention

The electrode that transmits mid-infrared ray or infrared ray can be obtained by configuring the electrode with the wire grid polarizer, and the near field light can be generated in the vicinity of the pn junction part by applying the forward bias voltage between the pair of electrodes and irradiating with the mid-infrared ray or the infrared ray, so that it is possible to easily obtain the light-receiving element that is sensitive to the long-wavelength light such as infrared ray.

Accordingly, in producing the light-receiving element that is sensitive to the long-wavelength light such as infrared ray, material selection restricted according to a band gap is not needed, so that it is possible to overcome disadvantages such as adverse effect on a human body, instability of a material, difficulty in a device process, and complexity of a production process.

### BRIEF DESCRIPTION OF DRAWINGS

FIG. 1 is a diagram illustrating a light-receiving element according to one or more embodiments of the present invention.

FIG. 2 is a diagram illustrating a planar structure of a wire grid polarizer according to one or more embodiments of the present invention.

### DESCRIPTION OF EMBODIMENTS

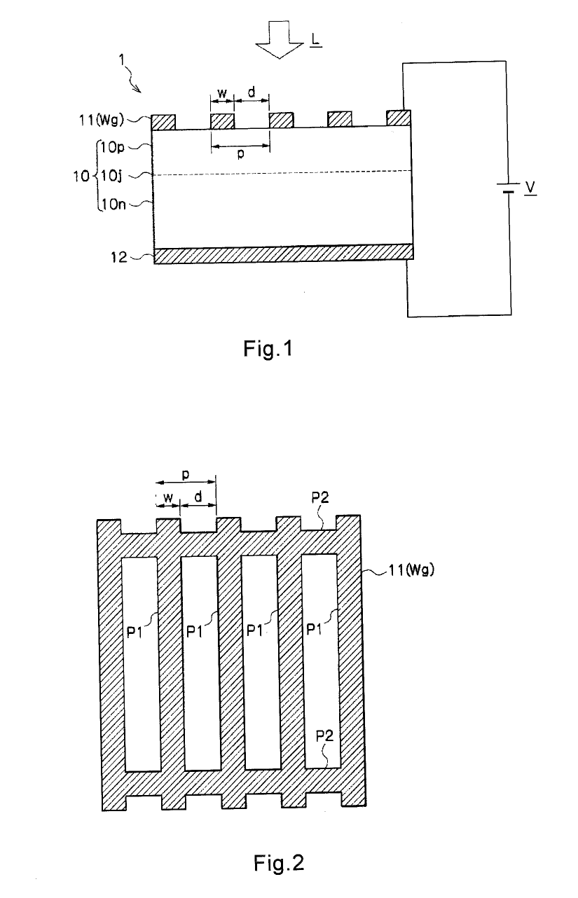

Hereinafter, one or more embodiments of the present invention will be described with reference to the drawings. FIG. 1 is a diagram illustrating a light-receiving element according to one or more embodiments of the present invention. A light-receiving element 1 is configured to include a semiconductor layer 10 including a pn junction part 10j and a pair of electrodes 11 and 12 interposing the pn junction part 10j. The semiconductor layer 10 may be configured, for example, with a p layer (p-type semiconductor layer) 10p and an n layer (n-type semiconductor layer) 10n. In this case, the pn junction part 10j is formed in the vicinity of a boundary between the p layer 10p and the n layer 10n. The semiconductor layer 10 may be a lamination of a plurality of layers or a layer formed on a substrate (not shown).

The p layer may be, for example, a p-type Si layer doped with a first substance on Si (silicon). Herein, the first substance may be a substance selected from, for example, group-13 elements (B (boron), Al (aluminum), and Ga (gallium)). The n layer may be, for example, an n-type Si layer doped with a second substance on Si (silicon). Herein, the second substance may be a substance selected from, for example, group-15 elements (As (arsenic), P (phosphorus), and Sb (antimony)).

At least one electrode 11 of the electrodes 11 and 12 is configured with a wire grid polarizer Wg. The wire grid polarizer Wg can transmit light having a specific wavelength that is irradiated on the pn junction part 10j in applying the later-described anneal process, and the electrode 11 of the side that is irradiated with the light is conductive. The electrode 12 of the side that is not irradiated with the light may be configured with a metal electrode layer or the like. In a case where light is irradiated from both sides of the pn junction part 10j, both electrodes 11 and 12 are configured with the wire grid polarizers Wg.

In the light-receiving element 1, near field light (dressed photon) is generated in the vicinity of the pn junction part 10j by an anneal process. As illustrated in FIG. 1, the anneal process is applying a forward bias voltage V to the pn junction part 10j through the electrodes 11 and 12 and irradiating the pn junction part with light L having a specific wavelength, and thus, a light-receiving portion that is sensitive to the light having the specific wavelength irradiated on the pn junction part 10j is formed.

In the anneal process, in the state where the forward bias voltage V is applied, in a case where a wavelength according to an energy absorption edge corresponding to a band gap width of the pn junction part 10j is set to an absorption edge wavelength, the light L having a specific wavelength that is longer than the absorption edge wavelength is irradiated. In a case where the light having a wavelength longer than the absorption edge wavelength is irradiated, since the energy of the light cannot reach the band gap width of the pn junction part 10j, electrons in the conduction band cannot be excited. Therefore, like a general pn junction, although the light is irradiated, by applying the forward bias voltage, holes are moved to the n layer 10n side, and electrons are moved to the p layer 10p side, so that Joule heat associated with the movement of electrons is generated.

The site where a particularly large amount of Joule heat is generated is the pn junction part 10j, the surface of the n layer 10n, the surface of the p layer 10p where high potential difference occurs. Since the Joule heat is generated, flowability is increased in the vicinity of the pn junction part 10j, so that the surface shape or dopant distribution is changed randomly in the vicinity of the pn junction part 10j. Therefore, the near field light is generated based on the irradiated light. The state in the vicinity of the pn junction part 10j where the near field light is generated can be enlarged by keeping on performing the anneal process. In addition, the state can be fixed by decreasing the Joule heat.

In the light-receiving element 1 formed by applying the anneal process, when the light having the specific wavelength irradiated in the anneal process is received, the state where the near field light is already generated appropriately with respect to the wavelength is formed, so that the near field light is generated in a large area. The light received by using the generated near field light is excited by multiple stages through vibration levels. Finally, electrons are excited to the conduction band, and thus, a function as a light-receiving element that is sensitive to the light having a specific wavelength can be obtained.

FIG. 2 is a diagram illustrating a planar structure of a wire grid polarizer functioning as a light-transmission electrode formed at the side that is irradiated with the light having the specific wavelength. The wire grid polarizer Wg may be made of a conductive metal such as Al, Zn, Ti, Ag, or Au. The wire grid polarizer has vertical line patterns P1 having a width W, an interval d, and a pitch p and horizontal line patterns P2 connecting all the vertical line patterns so as to equalize the potentials of the vertical line patterns.

When a minimum value of a transmission light wavelength is denoted by λmin, the pitch p of the wire grid polarizer Wg has a relationship of p≦λmin/2. Therefore, in a case where the above-described specific wavelength is 5 μm or more of infrared ray, the pitch is set to p≦2.5 μm. In addition, the interval d and the width W of the wire grid polarizer Wg become parameters influencing a current density distribution in the vicinity of the pn junction part 10j. In a case where the thickness of the p layer is set to about 1 μm, in order to secure a uniform current density distribution in the pn junction part 10j, the interval is set to d≦2 μm.

Examples of the configuration of the wire grid polarizer Wg are described as follows. In a first example, an antireflection film of Ni—Cr was prepared on both surfaces of a silicon wafer having a thickness of 0.5 mm, and Au wire grid having a height (depth) of 100 nm was formed on one surface. A pitch P of the wire grid was set to 0.56 μm with respect to a design wavelength of 3 to 6 μm of transmission light, and a line width W of the wire grid was set to 60% of the pitch P. A second example was configured to be the same as the first example except that the pitch P of the wire grid was set to 0.84 μm with respect to a design wavelength of about 10 μm of transmission light. In the first and second examples, transmission rates of S polarization (polarization component perpendicular to the direction of grid) in the design wavelength ranges of the transmission light are 70% or more, and Ni—Cr of the antireflection film is conductive. Therefore, each of the wire grid polarizers serves as the electrode 11 for applying the above-described anneal process.

In this manner, in the light-receiving element 1, the electrode 11 is used as the wire grid polarizer Wg, and near field light can be generated in the vicinity of the pn junction part 10j by applying a forward bias voltage V between the electrodes 11 and 12 and irradiating the pn junction part 10j between the electrodes 11 and 12 with mid-infrared ray of 3 μm or more. Therefore, a light-receiving portion that is sensitive to mid-infrared ray having a wavelength of 3 μm or more can be formed in the vicinity of the pn junction part 10j without being restricted according to the band gap of the pn junction part 10j.

In the light-receiving element 1 formed in this manner, the side where the wire grid polarizer Wg is formed is used as a light-receiving surface, and long wavelength mid-infrared ray having a wavelength of 3 μm or more that is incident on the light-receiving portion formed in the vicinity of the pn junction part 10j through the light-receiving surface can be detected as a change in electromotive force between the electrodes 11 and 12. In this case, an appropriate reverse bias voltage may be applied between the electrodes 11 and 12.

As described above, in the light-receiving element 1 according to one or more embodiments of the present invention, in producing the light-receiving element that is sensitive to long wavelength light such as infrared ray, material selection restricted according to a band gap is not needed, so that it is possible to overcome disadvantages such as adverse effect on a human body, instability of a material, difficulty in a device process, and complexity of a production process.

### EXPLANATION OF REFERENCE NUMERALS

1: light-receiving element, 10: semiconductor layer,
10p: p layer, 10n: n layer, 10j: pn junction part,
11, 12: electrode
Wg: wire grid polarizer

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

1. A light-receiving element comprising:
a semiconductor layer comprising a pn junction part; and
a pair of electrodes that interpose the pn junction part,
wherein near field light is generated in the vicinity of the pn junction part by applying a forward bias voltage between the pair of electrodes and irradiating the pn junction part with light having a specific wavelength, and
wherein an electrode of the irradiated pair of electrodes is configured with a wire grid polarizer that transmits the light having the specific wavelength.

2. The light-receiving element according to claim 1, wherein the light having the specific wavelength is a mid-infrared ray having a wavelength of 3 μm or more.

3. A production method for a light-receiving element, comprising:
forming electrodes in a semiconductor layer comprising a pn junction part to interpose the pn junction part;
forming at least one of the electrodes with a wire grid polarizer that transmits light having a specific wavelength; and
generating near field light in the vicinity of the pn junction part by applying a forward bias voltage between the electrodes and irradiating the pn junction part with the light having the specific wavelength through the wire grid polarizer.
